(19) United States
(12) Patent Application Publication
(10) Pub. No.: US 2015/0261261 A1
(43) Pub. Date: Sep. 17, 2015

(54) SENSOR EMBEDDED IN GLASS AND PROCESS FOR MAKING SAME

(71) Applicant: CORNING INCORPORATED, CORNING, NY (US)

(72) Inventors: Venkata Adiseshaiah Bhagavatula, Big Flats, NY (US); Nagaraja Shashidhar, Painted Post, NY (US)

(21) Appl. No.: 14/645,750

(22) Filed: Mar. 12, 2015

Related U.S. Application Data
(60) Provisional application No. 62/036,320, filed on Aug. 12, 2014.
(60) Provisional application No. 61/953,019, filed on Mar. 14, 2014.

(51) Int. Cl. G06F 1/16; C03C 15/00; C03B 23/037; C03B 29/02; H05K 5/03; G06K 9/00

(52) U.S. Cl. CPC G06F 1/1656; H05K 5/03; G06K 9/00053; C03B 23/037; C03B 29/025; C03C 15/00

(57) ABSTRACT

A cover assembly for an electronic device includes a sensor element embedded in the opening of a substrate such that the first side of the sensor element is flush with the first surface of the substrate. This allows for conductive elements in the sensor element to be present at a surface of the cover assembly. The conductive elements are inside via holes. A sensor substrate with the via holes can be formed using a redraw process or a laser damage and etch process.

### CROSS-REFERENCE TO RELATED APPLICATIONS

This application claims the benefit of priority under 35 U.S.C. §119 of U.S. Provisional Application Ser. Nos. 62/036,320 filed on Aug. 12, 2014 and 61/953,019 filed on Mar. 14, 2014, the content of each is relied upon and incorporated herein by reference in its entirety.

### FIELD

The disclosure relates to a sensor embedded in glass and a process for making the same, and more particularly to a cover assembly for an electronic device having a sensor element embedded in a glass substrate.

### BACKGROUND

There is an increasing demand to incorporate sensor elements, such as fingerprint sensors, into electronic devices having touchscreens, such as cellular phones, tablets, and notebooks. Sensor elements can be convenient and useful for consumers. For example, fingerprint sensors are advantageous because they add an extra layer of security beyond password protection so that if your device is stolen, the thief cannot gain access to your personal information stored in the device without your fingerprint.

Many electronic devices having touchscreens have a protective cover made of glass. The challenge with incorporating sensor elements, such as fingerprint sensors, into such devices is that if the sensor element is placed under the cover glass, then the sensitivity and resolution of the sensor is not adequate if the cover glass is too thick. As such, a need exists to embed sensor elements within the protective cover glass so that the thickness of the cover glass does not affect the sensitivity of the sensor element.

### SUMMARY

One embodiment of the disclosure is a cover assembly for an electronic device including a substrate comprising a first surface, a second surface opposing the first surface, and an opening in the first surface; a sensor element comprising a first side and a second side opposing the first side, wherein the sensor element is embedded in the opening such that the first side of the sensor element is flush with the first surface of the substrate; a gap between a perimeter of the opening in the substrate and a perimeter of the first side of the sensor element; and a polymeric material disposed in the gap such that the polymeric material is flush with the first side of the sensor element and the first surface of the substrate.

In some embodiments, the sensor element can include a substrate selected from the group consisting of glass, ceramic, glass ceramic, and polymeric material. In some embodiments, the sensor element substrate has a surface that is the first side of the sensor element. In some embodiments, the sensor element substrate has a plurality of via holes extending therethrough. The via holes can be substantially rectangular or substantially circular in shape. The via holes can be filled with a conductive element, wherein the conductive elements can be electrically conductive or thermally conductive.

In some embodiments, a wear resistant layer is disposed on the surface of the sensor element substrate. In some embodiments, the sensor element further comprises a circuit assembly connected to a surface of the sensor element substrate opposing the first side of the sensor element. In some embodiments, the sensor element is a fingerprint sensor. In some embodiments, the sensor element substrate is a different color than the substrate. In some embodiments, the polymeric material has an index of refraction substantially the same as the substrate.

In some embodiments, the sensor element includes a diffractive optical element that transmits light. In other embodiments, the sensor element includes a plurality of waveguides formed from fibers conducting acoustic waves.

A further embodiment of the disclosure is an electronic device comprising the cover assembly described above.

A still further embodiment of the disclosure is a process for making a cover assembly for an electronic device, the process including forming a sensor substrate having a first surface, an opposing second surface, and a plurality of via holes extending from the first surface to the second surface; filling the plurality of via holes with a conductive element; placing the sensor substrate into an opening extending from a first surface to an opposing second surface of a substrate such that there is a gap between a perimeter of the opening in the substrate and a perimeter of the first side of the sensor substrate, wherein the first surface of the sensor substrate is flush with the first surface of the substrate; and filling the gap with a polymeric material such that the polymeric material is flush with the first side of the sensor substrate and the first surface of the substrate.

In some embodiments, forming the sensor substrate includes placing an assembly of alternating glass slabs and sacrificial glass slabs between two glass plates to form a preform; pulling the preform through a heating zone to redraw the preform, wherein the preform is proportionally shrunk; and etching the sacrificial glass slabs after redrawing to form a plurality of via holes. In some embodiments, the following steps can be performed prior to etching the sacrificial glass slabs: placing a plurality of the shrunken preforms between two plates of glass to form a second preform; and pulling the second preform through the heating zone to redraw the second preform, wherein the second preform is proportionally shrunk. In some embodiments, the sacrificial glass slabs have a different composition than the glass slabs and the glass plates, and wherein the sacrificial glass slabs dissolve faster in an etching solution than the glass slabs and the glass plates. In some embodiments, the glass slabs and the glass plates have photoinitiated seed crystals and the process further includes photoinitiating the seed crystals after redrawing, but before etching the sacrificial glass to form a glass ceramic sensor substrate.

In some embodiments, forming the sensor substrate includes translating a pulse laser across the sensor substrate in a desired location for each of the plurality of via holes to form a laser damaged region; and etching the laser damaged region to form the plurality of via holes.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the claims. The accompanying drawings are included to provide a further understanding, and are incorporated in and constitute a part of this specification. The drawings illustrate one or more embodiment(s), and together with the description serve to explain principles and operation of the various embodiments.

### BRIEF DESCRIPTION OF THE DRAWINGS

FIG. 1 is a top plan view of an exemplary electronic device having a cover assembly with an embedded sensor element;

FIG. 2A is a first exemplary cross-sectional view of the exemplary electronic device of FIG. 1 taken along line A-A.

FIG. 2B is a second exemplary cross-sectional view of the exemplary electronic device of FIG. 1 taken along line A-A.

FIG. 3 is a top plan view of the exemplary sensor element of FIG. 1.

FIG. 4 is a top plan view of alternative exemplary sensor element.

FIG. 5 is a top plan view an array of sensor substrates with via holes formed by a laser damage and etch process.

FIGS. 6A-6C illustrate exemplary preforms formed during a redraw process for forming a sensor substrate having via holes.

FIG. 7 is a perspective view of an exemplary assembly used in positioning a sensor element in an opening of a cover substrate.

### DETAILED DESCRIPTION

Reference will now be made in detail to the present preferred embodiment(s), an example(s) of which is/are illustrated in the accompanying drawings. Whenever possible, the same reference numerals will be used throughout the drawings to refer to the same or like parts.

Incorporating sensor elements into electronic devices having touchscreens with a protective glass cover poses some challenges. For example, the sensor element is typically positioned under the protective glass in order to protect the sensor element from damage. However, this reduces the sensitivity and resolution of the sensor element. Also, in some instances, if the glass covering the sensor element is too thick, then the sensor element will not operate properly. For example, with capacitive fingerprint sensors, the sensor sensitivity decreases rapidly with the thickness of the glass substrate covering it. The glass thickness would need to be less than 200 μm for the sensor to function in a diminished capacity and less than 5 μm for best performance. However, a cover glass with a thickness of less than 5 μm would not provide the best protection in terms of damage resistance.

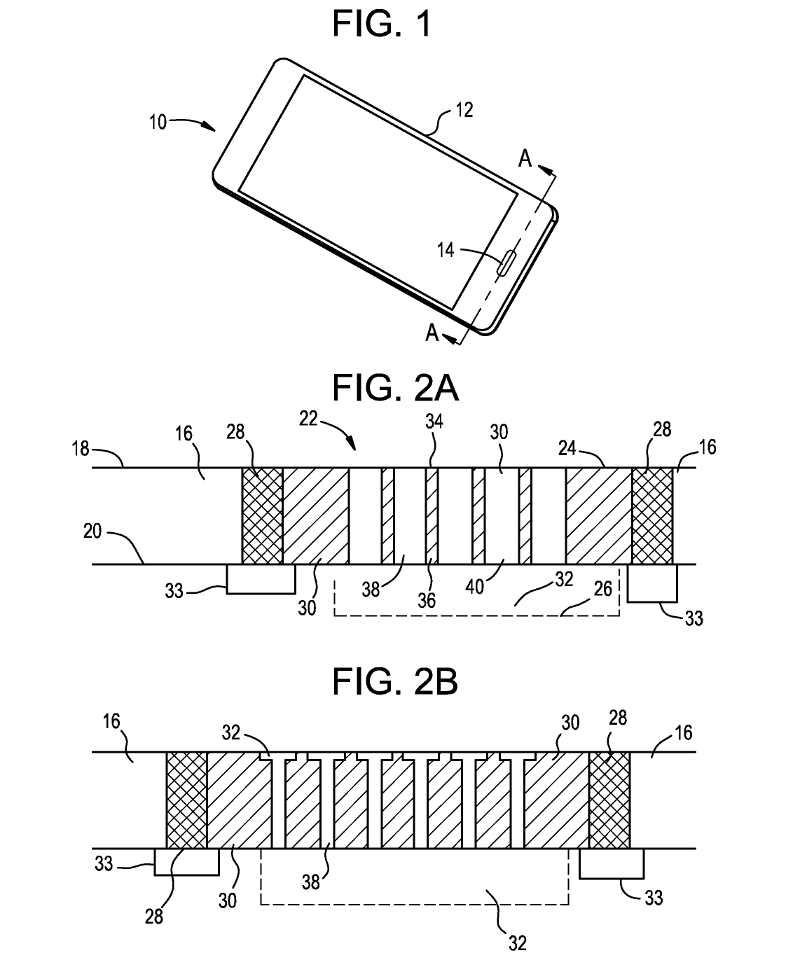

A solution to the above problems is to embed a sensor element within a cover glass such that the sensor element is flush with an outer surface of the cover glass. As used herein, two surfaces are flush with each other when the plane of each of the surfaces is offset from one another by 200 microns or less. FIGS. 1 and 2 illustrate an exemplary embodiment of an electronic device 10 having a cover assembly 12 with a sensor element 14 embedded in a cover substrate 16. In some embodiments, cover substrate 16 can be glass. Cover substrate 16 can have an outer surface 18, which forms an exterior of electronic device 10, and an inner surface 20, which faces an interior of electronic device 10. Cover substrate 16 can have an opening 22 in outer surface 18. In some embodiments, as shown for example in FIG. 2A, opening 22 can extend from outer surface 18 of cover substrate 16 to inner surface 20 of cover substrate 16.

Sensor element 14 having a first side 24 and an opposing second side 26 can be positioned in opening 22 of cover substrate 16. In some embodiments, first side 24 of sensor element 14 is flush with outer surface 18 of cover substrate 16. As shown in FIG. 2A, first side 24 of sensor element 14 can be flush with outer surface 18 of cover substrate 16 across an entire width of first side 24 (e.g., first side 24 of sensor element 14 can be coplanar with outer surface 18 of cover substrate 16). In some embodiments, there can be a gap between the perimeter of first side 24 of sensor element 14 and the perimeter of opening 16. In some embodiments the size of the gap can be in a range from about 0.1 mm to about 0.5 mm. In some embodiments the size of the gap can be about 0.1 mm, about 0.2 mm, about 0.3 mm, about 0.4 mm, or about 0.5 mm. A polymeric material 28 can be disposed in the gap to provide shock absorbance, and thereby mechanically isolate sensor element 14 from cover substrate 16 to prevent or minimize a stress concentration at an interface between sensor element 14 and cover substrate 16. In some embodiments, polymeric material 28 can be an elastomeric adhesive. In some embodiments, polymeric material 28 can be a silicon-based material, a polyurethane-based material, or an acrylate-based material. In some embodiments, polymeric material 28 can be, for example, silicone-based Permatex 81730 or acrylate-based Loctite 37613. In some embodiments, polymeric material 28 can have an elastic modulus of 500 MPa or less, 50 MPa or less, 5 MPa or less, or 0.5 MPa or less. In some embodiments, polymeric material 28 can have a refractive index that matches or that is substantially the same as the refractive index of cover substrate 16. In some embodiments, polymeric material 28 is disposed in the gap such that polymeric material 28 is flush with first side 24 of sensor element 14 and outer surface 18 of cover substrate 16.

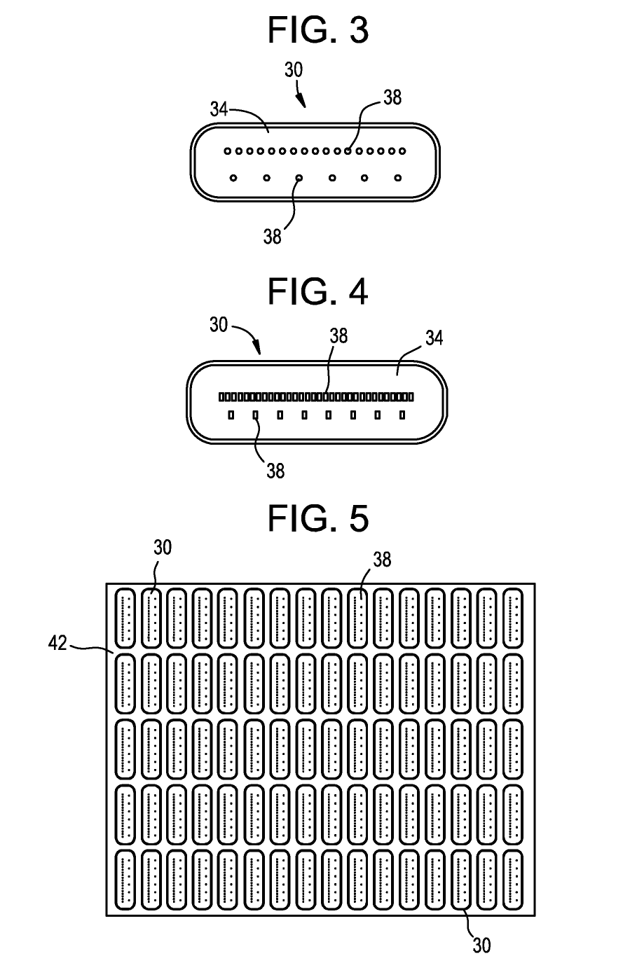

In some embodiments, sensor element 14 can include but is not limited to, a fingerprint sensor, a thermometer, a pulse oximeter, a pressure sensor, or an optics-based sensor Sensor element 14 can include a sensor substrate 30 and a circuitry assembly 32. Sensor substrate 30 can have a first surface 34, which can be the same as first side 24 of sensor element 14, and an opposing second surface 36. Sensor substrate 30 can be a suitable material, including, but not limited to glass, ceramic, glass ceramic, silicon, or a polymeric material. In some embodiments, sensor substrate 30 can include a coating or layer, for example a sapphire layer or corundum film. In some embodiments, sensor substrate 30 can have an array of via holes 38 extending from first surface 34 to second surface 36. Exemplary arrangements of via holes 38 are shown in FIGS. 3 and 4. In some embodiments, via holes 38 are arranged so that there is a resolution of about 700 dpi, about 600 dpi, about 500 dpi, or about 400 dpi. Via holes 38 can be shaped as needed to maximize resolution and/or signal to noise ratio. For example, via holes 38 can be substantially circular in shape as shown in FIG. 3 or can be substantially rectangular in shape as shown in FIG. 4. As discussed below, methods for maximizing the resolution and/or signal to noise ratio of the via holes, include, but are not limited to a laser damage and etch process or a redraw process.

Via holes 38 can be filled with a conductive element 40, such as metal, including, but not limited to tin (e.g., solder), copper, gold, silver, platinum, tungsten, or alloys thereof. In some embodiments, conductive elements 40 can be electrically conductive, thermally conductive, or combinations thereof. In some embodiments, conductive element 40 can transmit energy from first surface 34 of sensor substrate (which is also first side 24 of sensor element 14) to circuit assembly 32, which is connected to second surface 36 of sensor substrate 30. Circuit assembly 32 can vary depending upon the particular type of sensor and can include circuit assemblies known in the art. Also, circuit assembly 32 can be connected to sensor substrate 30 through means known in the art. The presence of via holes 38 and conductive elements 40 at first surface 34 of sensor substrate (which is also first side 24 of sensor element 14) means that via holes 38 and conductive elements 40 are flush with outer surface 18 of cover substrate 16. As such, conductive elements 40 can be directly exposed to the energy source which they transmit without the presence of a protective glass layer above. As a result, the thickness of electronic device 10 can be minimized and sensor element 14 can work properly without interference of a protective glass layer.

In some embodiments, a thickness of sensor element 14 can be greater than a thickness of cover substrate 16. In such embodiments, sensor substrate 30 can have substantially the same thickness as cover substrate 16 and circuitry assembly 32 is not in opening 22. In other embodiments, sensor element 14 has a thickness substantially the same as the thickness of cover substrate 16. In some embodiments, sensor substrate 30 can have a thickness less than the thickness of cover substrate 16 and a portion of circuit assembly 32 can be present in opening 22 and a portion can extend beyond inner surface of cover substrate 16.

In some embodiments, sensor substrate 30 can be opaque so that circuit assembly 32 is not visible through sensor substrate 30. In some embodiments, sensor substrate 30 can be an opaque ceramic or glass ceramic. In some embodiments, sensor substrate 30 can be tinted or dyed glass. Another benefit of substrate 30 being opaque is that it can make the sensor element visible to a user because it is a different color from cover substrate 16. In some embodiments, sensor substrate 30 can be shaped to indicate which direction to swipe sensor element 14 in order to activate it, for example in the shape of an arrow.

In some embodiments, sensor element 14 can be backlighted to highlight where sensor element 14 is located in cover assembly 12. In some embodiments, as shown for example in FIGS. 2A and 2B, a light emitting film 33 can be positioned below polymeric material 28 to provide the backlighting. In such embodiments, light emitting film 33 can extend beneath polymeric material 28 and a portion of inner surface 20 of cover substrate 16 and second surface 26 of sensor substrate 30. Light emitting film 33 can be any suitable material that will emit light that will transmit through polymeric material 28 so that it can be seen from outer surface 18 of cover substrate 16. Suitable materials include, but are not limited to, inorganic electroluminescent films, organic electroluminescent films, and organic light-emitting diode (OLED) films. In some embodiments, light emitting film 33 can be a blue electroluminescent film with or without added phosphors to change the color. In some embodiments, polymeric material 28 can be filled with light scattering particles or beads. For example, in some embodiments, polymeric material 28 can include transparent beads or particles that have a different index of refraction than polymeric material 28. In other embodiments, polymeric material 28 can include fluorescent beads or particles that emit a desired color after absorbing the light emitted from light emitting film 33. In some embodiments, light emitting film 33 can be electrically connected to circuit assembly 32 so that circuit assembly 32 can control the on/off state of light emitting film 33. In some embodiments, circuit assembly 32 can include controls for pulsing or flashing light emitting film 33.

A process for making cover assembly 12 of electronic device 10 with an embedded sensor element 14 can include preparing sensor substrate 30 with via holes 38, filling via holes 38 with conductive elements 40, attaching circuitry assembly 32 to sensor substrate 30 to form sensor element 14, placing sensor element 14 in opening 22 of cover substrate 16, and filling the gap between the perimeter of opening 22 and the perimeter of sensor element 14 with polymeric material 28. The above is merely an exemplary listing of steps for making the cover assembly and can include additional or fewer steps.

In some embodiments, sensor substrate 30 with via holes 38 can be formed using a laser damage and etch process. In such embodiments, multiple sensors substrates with via holes 38 can be formed on a single plate 42, as shown for example in FIG. 5. Via holes 38 can be formed using a laser damage and etch process, such as the process described in U.S. patent application Ser. No. 14/092,544 filed Nov. 27, 2013, which is hereby incorporated by reference in its entirety. In brief, a pulsed laser beam can be translated across plate 42 to create laser damage in plate 42 in areas corresponding to where via holes 38 are desired. Then the laser damaged areas can be etched to form via holes 38. In some embodiments, when sensor substrate 30 is glass then plate 42 is glass. In other embodiments, when sensor substrate 30 is glass ceramic, then plate 42 is in a glass state for the laser damage and etch process, and can then be subsequently cerammed to form a glass ceramic, using known techniques. FIG. 3 illustrates an exemplary sensor substrate 30 with via holes 38 formed using a laser damage and etch process. In some embodiments a laser damage and etch process can result in circular shaped vias. In some embodiments, the vias can have a diameter of about 40 μm. In some embodiments, via holes 38 can have a center-to-center spacing of 50 μm to achieve a resolution of 500 dpi or a center-to-center spacing of 62.5 μm to achieve a resolution of 400 dpi.

In some embodiments, a laser damage and etch process can include a first step of using reactive ion etching to precision etch shallow indents 37 on first surface 34 of sensor substrate 30, as shown, for example, in FIG. 2B. Then, sensor substrate 30 can be laser damaged at the center of each indent 37. Next, the laser damaged areas can be etched to form via holes 38. In such embodiments, a perimeter of indents 37 can be larger than a perimeter of via holes 38 and indents 37 can be spaced closer together than via holes 38.

In other embodiments, sensor substrate 30 with via holes 38 can be formed using a redraw process. In such embodiments, a preform can be formed wherein alternating slabs of glass and sacrificial glass are placed between two plates of glass. In some embodiments, the slabs of glass and the slabs of sacrificial glass have the same length and height, but have different widths. In some embodiments, the width of the slabs of the sacrificial glass is less than the width of the slabs of glass. In some embodiments, the width of the slabs of glass can be less than the width of the slabs of sacrificial glass. The preform can then be redrawn using conventional techniques, for example by pulling the preform through a heating zone to form a shrunken preform. The redraw process proportionally shrinks the preform. In some embodiments, the redraw ratio can be a 5 times reduction, a 10 times reduction, a 15 times reduction, or a 20 times reduction. For example, if the preform measured 80 mm by 200 mm and the redraw ratio was 20, then the shrunken preform would measure 4 mm by 10 mm. In some embodiments, the sacrificial glass in the shrunken preform can be etched away to form the via holes. In some embodiments, the etching process can include placing the shrunken preform in an etching solution to etch away or dissolve the sacrificial glass. The etching solution can be an acid solution. In some embodiments, the sacrificial glass has a different composition than the glass slabs and the glass plates. For example, the sacrificial glass can dissolve faster in the etching solution than the glass slabs and glass plates. Examples of glass compositions with different dissolving rates are taught, for example, in U.S. Pat. Nos. 4,102,664; 5,342,426; and 5,100,452, each of which is hereby incorporated by reference in its entirety. In such embodiments, the shrunken preform can be placed in the etching solution without masking the glass slabs and glass plates because the sacrificial glass will be etched away before significant etching of the glass slabs and glass plates can occur.

In some embodiments, the glass slabs and glass plates can include a photoinitiated seed crystal In such embodiments, after the redrawing process, but before etching the sacrificial glass away to form the via holes, the sensor substrate can be exposed to light to activate the photoinitiated seed crystals to turn the glass into glass ceramic.

In some embodiments, depending on the desired size of the via holes, the preform assembly and redraw process can be performed multiple times. For example, after forming a plurality of shrunken preforms, the shrunken preforms can then be assembled end-to-end and placed between two sheets of glass and subjected to the redraw process again to form a second preform. In such embodiments, the sacrificial glass can be etched away after the final redraw process. In some embodiments, prior to performing the last redraw process the assembly of shrunken preforms can be surrounded on the top, bottom, left side, and right side with four sheets of glass, one on each side, rather than between two sheets of glass.

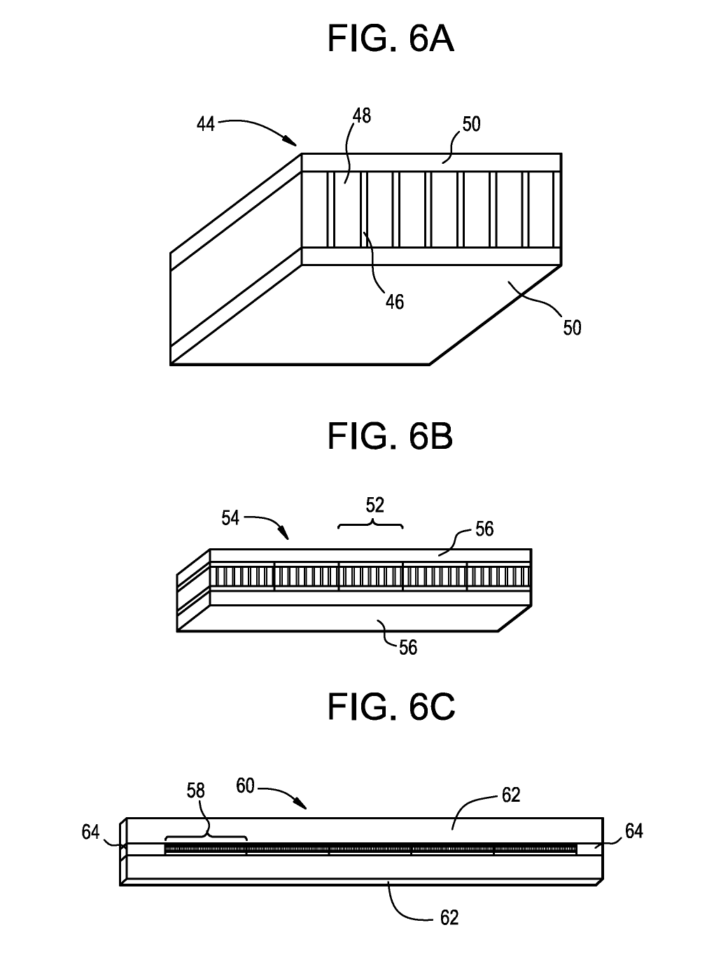

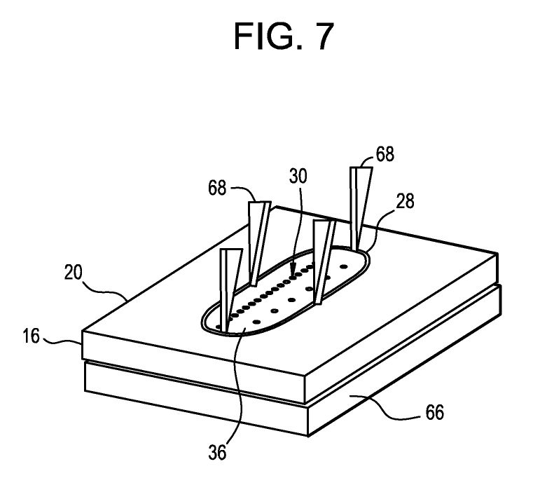

FIGS. 6A-6C illustrate an exemplary redraw process including three redraw steps. FIG. 6A illustrates a first preform 44 including an assembly of alternating glass slabs 46 and sacrificial glass slabs 48 sandwiched between two glass sheets 50. In some embodiments, eight glass slabs 46 and eight sacrificial glass slabs can be assembled in the alternating arrangement. Exemplary dimensions for sacrificial glass slabs 48 can be 8 mm wide by 24 mm thick, exemplary dimensions for the glass slabs 46 can be 2 mm wide by 24 mm thick, and exemplary dimensions for glass sheets 50 can be 80 mm wide by 32 mm thick. This results in first preform being 80 mm wide by 32 mm thick. First preform 44 can be subjected to a redraw process and shrunken to form a shrunken first preform 52. In some embodiments, the redraw ratio can be eight such that first preform is proportionally shrunken from being 80 mm wide by 32 mm thick to being 10 mm wide by 4 mm thick. FIG. 6B illustrates a second preform 54 including an assembly of shrunken first preforms 52 arranged end to end between two glass sheets 56. In some embodiments, five shrunken first preforms 52 measuring 10 mm wide by 4 mm thick can be assembled between glass sheets 56 that are each 50 mm wide by 3 mm thick. Second preform 54 can be subjected to a redraw process and shrunken to form a shrunken second preform 58. In some embodiments, the redraw ratio can be five such that a second preform 54 measuring 50 mm wide by 10 mm thick can be proportionally shrunken so that shrunken second preform 58 measures 10 mm wide by 2 mm thick. FIG. 6C illustrates a third preform 60 including an assembly of shrunken second preforms 58 bounded by two glass sheets 62 on the top and bottom and two glass sheets 64 on the left and right. In some embodiments, five shrunken second preforms 58 measuring 10 mm wide by 2 mm thick can be assembled between glass sheets 62 having dimensions of 70 mm wide by 4 mm thick on the top and bottom and glass sheets 64 having dimensions 10 mm wide by 2 mm thick on the left and right. Third preform 60 can be subjected to a redraw process and shrunken to form a shrunken third preform. In some embodiments, the redraw ratio can be five such that a third preform 60 having dimensions of 70 mm wide by 10 mm thick can be proportionally shrunken to form a third shrunken preform having dimensions of 14 mm wide by 2 mm thick. In some embodiments, the shrunken third preform can be sliced into slices, for example 0.6 mm thick slices. In some embodiments, the shrunken third preform can be sliced into slices have the same thickness as cover substrate 16. The slices can then be further processed to etch away the sacrificial glass to create the via holes. In this exemplary process, a total size reduction of 200 can be achieved (8×5×5).

FIG. 4 illustrates an exemplary sensor substrate 30 with via holes 38 formed using the redraw process. In some embodiments, the redraw process results in via holes that are substantially rectangular in shape, for example having a width of about 40 μm and a length of at least about 100 μm. In one embodiment, the dimensions can be 40 μm by 120 μm. In some embodiments, a gap between the edge of one via hole to the edge of an adjacent via hole can be about 10 μm. An array of rectangular shaped via holes can be advantageous over circular shaped via holes because it increases the signal to noise ratio (S/L) by maximizing the concentration of via holes in a given area.

In some embodiments, once via holes 38 are formed in sensor substrate 30, via holes 38 can be filled with conductive elements 40. As discussed above, in some embodiments, conductive elements 40 are metal. In such embodiments, via holes 38 can be filled with metal to form conductive elements 40 using techniques known in the art, including, but not limited to, sputtering, electroplating, metal paste application, vapor deposition, or combinations thereof. In some embodiments, when a laser damage and etch process is used to form the via holes, an array of sensor substrates can be formed from a single substrate plate, for example plate 42. After filling the via holes, the individual sensor substrates can be formed using dicing and shaping techniques known in the art. In other embodiments, when a redraw process is used to form the sensor substrate with via holes, the redrawn shrunken preform can be sliced into sensor elements and the sensor elements can be attached to a plate with a temporary thermoplastic adhesive to perform the processes of etching the sacrificial glass and filling the via holes.

In some embodiments, after via holes 38 are filled with conductive elements 40, first surface 34 of sensor substrate 30 can be polished using know techniques to remove excess metal protruding from via holes 38. In some embodiments, first surface 34 of sensor substrate 30 can be coated with a wear resistant layer using known techniques. In some embodiments, the wear resistant layer can be transparent. The material for the wear resistant layer can include, but is not limited to a layer of silicon dioxide or dialuminum trioxide.

Circuitry assembly 32 can be formed and attached to second surface 36 of sensor substrate 30 using conventional techniques, thereby forming sensor element 14. For example, in some embodiments, layers of the circuit assembly 32 can be directly deposited on second surface 36 of sensor substrate 30, layer by layer. In other embodiments, circuit assembly 32 can be assembled apart from sensor substrate 30 and then attached to second surface 36 of sensor substrate 30, for example with the use of conductive adhesive or solder.

As shown in FIG. 7, a process for positioning sensor element 14 in cover assembly 12 can include placing outer surface 18 of cover substrate 16 against a plate 66. Sensor element 14 can be positioned in opening 22 of cover substrate 16 such that first side 24 of sensor element 14 contacts plate 66. Having outer surface 18 of cover substrate 16 and first side 24 of sensor element 14 contact plate 66, as shown in FIG. 7, can ensure that outer surface 18 and first side 24 are flush. For simplicity, FIG. 7 does not depict circuit assembly 32. Wedges 68 can be used to position sensor element 14 within a center of opening 22. Next, polymeric material 28 can be dispensed in the gap between sensor element 14 and opening 22. In some embodiments, a suitable pressure can be applied to plate 66 and sensor element 14 to prevent polymeric material 28 from running between plate 66 and cover substrate 16. Then, polymeric material 28 can be cured. In some embodiments, plate 66 can have a release coating to prevent polymeric material 28 from adhering to plate 66. In some embodiments, plate 66 can be a glass plate. In such embodiments, an ultraviolet light can be positioned beneath plate 66 and the ultraviolet light can pass through plate 66 to at least partially cure polymeric material 28. In some embodiments, if the ultraviolet light does not fully cure polymeric material 28, then polymeric material 28 can be heated to fully cure polymeric material 28 once cover assembly 12 is removed from plate 66. In some embodiments, once sensor element 14 is placed in cover assembly 12 and polymeric material 28 is cured, light emitting film 33 can be deposited using standard techniques, including but not limited to bonding with an adhesive, such as an epoxy.

In some embodiments, sensor element 14 can be a pressure sensor. In such embodiments, via holes 38 are not filled. In some embodiments, via holes are not formed in sensor substrate 30. For example, sensor element 14 can be an optics-based sensor and includes a diffractive optical element that transmits light. In some embodiments, sensor element 14 can be a pulse oximeter and sensor substrate 30 can be a transmissive glass.

In some embodiments, sensor element 14 can be a bundle of waveguides conducting ultrasonic or acoustic waves perpendicular to the side of the sensor element flush with outer surface 18 of cover substrate 16. In such embodiments, a fiber bundle having a plurality of fibers can be formed to a desired shape and chopped to a desired thickness for sensor element 14. The chopped fiber bundle can be placed in opening 22 of cover substrate 16 and a gap between the perimeter of the chopped fiber bundle and the opening can be filled with polymeric material 28. The fibers can serve as the waveguides. In some embodiments, each fiber in the fiber bundle can have a core and a cladding surrounding the core. In some embodiments, the core can have a higher shear wave propagation velocity than cladding. In some embodiments, the fiber bundles can be made from a combination of different glasses or from a combination of different polymers. In some embodiments, the cladding can be glass and the core can be polymeric.

In some embodiments, the via holes or waveguides can be arranged in one or two rows to form a swipe sensor, such that the sensor is activated by a user swiping his finger across the row(s) of via holes or waveguides. In other embodiments, the via holes or waveguides can be arranged in a matrix of a plurality of rows and columns, for example in a 5 by 5 matrix, to form an area sensor.

As discussed above, disclosed herein is a cover assembly for an electronic device overcoming the challenges of incorporating sensor elements in electronic devices with a touchscreen, wherein a sensor element is embedded in an opening in a cover glass assembly such that the sensor element is flush with an outer surface of the cover glass assembly. This allows the conductive elements in the sensor element to be at the surface of the touchscreen. Also disclosed herein are methods of laser damage and etching and methods of redrawing for forming a sensor substrate for use in a sensor element in a manner that increases the resolution and/or signal to noise ratio of via holes.

It will be apparent to those skilled in the art that various modifications and variations can be made without departing from the spirit or scope of the invention.

What is claimed is:

1. A cover assembly for an electronic device, comprising:
a substrate comprising a first surface, a second surface opposing the first surface, and an opening in the first surface;
a sensor element comprising a first side and a second side opposing the first side, wherein the sensor element is embedded in the opening such that the first side of the sensor element is flush with the first surface of the substrate;
a gap between a perimeter of the opening in the substrate and a perimeter of the first side of the sensor element; and
a polymeric material disposed in the gap such that the polymeric material is flush with the first side of the sensor element and the first surface of the substrate.

2. The cover assembly of claim 1, wherein the sensor element further comprises a substrate selected from the group consisting of glass, ceramic, glass ceramic, and polymeric material.

3. The cover assembly of claim 2, wherein the sensor element substrate has a surface comprising the first side of the sensor element.

4. The cover assembly of claim 3, wherein the sensor element substrate has a plurality of via holes extending therethrough.

5. The cover assembly of claim 4, wherein the via holes are substantially rectangular.

6. The cover assembly of claim 4, wherein the via holes are substantially circular.

7. The cover assembly of claim 4, wherein each of the via holes is filled with a conductive element.

8. The cover assembly of claim 7, wherein the conductive elements are electrically conductive or thermally conductive.

9. The cover assembly of claim 3, wherein a wear resistant layer is disposed on the surface the surface of the sensor element substrate.

10. The cover assembly of claim 3, wherein the sensor element further comprises a circuit assembly connected to a surface of the sensor element substrate opposing the first side of the sensor element.

11. The cover assembly of claim 2, wherein the sensor element is a fingerprint sensor.

12. The cover assembly of claim 2, wherein the sensor element substrate is a different color than the substrate.

13. The cover assembly of claim 1, wherein the polymer material has an index of refraction substantially the same as the substrate.

14. The cover assembly of claim 1, wherein the sensor element comprises a diffractive optical element that transmits light.

15. The cover assembly of claim 1, wherein the sensor element comprises a plurality of waveguides formed from fibers that conduct acoustic waves.

16. The cover assembly of claim 1, further comprising a light emitting film positioned beneath the polymeric material.

17. An electronic device comprising the cover assembly of claim 1.

18. A process for making a cover assembly for an electronic device, the process comprising:
forming a sensor substrate having a first surface, an opposing second surface, and a plurality of via holes extending from the first surface to the second surface;
filling the plurality of via holes with a conductive element;
placing the sensor substrate into an opening extending from a first surface to an opposing second surface of a substrate such that there is a gap between a perimeter of the opening in the substrate and a perimeter of the first side of the sensor substrate, wherein the first surface of the sensor substrate is flush with the first surface of the substrate; and
filling the gap with a polymeric material such that the polymeric material is flush with the first side of the sensor substrate and the first surface of the substrate.

19. The process of claim 18, wherein forming the sensor substrate comprises:
placing an assembly of alternating glass slabs and sacrificial glass slabs between two glass plates to form a preform;
pulling the preform through a heating zone to redraw the preform, wherein the preform is proportionally shrunk;
etching the sacrificial glass after redrawing to form a plurality of via holes.

20. The process of claim 19, wherein forming the sensor substrate further comprises performing the following steps prior to etching the sacrificial glass:
placing a plurality of the shrunken preforms between two plates of glass to form a second preform; and
pulling the second preform through the heating zone to redraw the second preform, wherein the second preform is proportionally shrunk.

21. The process of claim 19, wherein the sacrificial glass slabs have a different composition than the glass slabs and the glass plates, and wherein the sacrificial glass slabs dissolve faster in an etching solution than the glass slabs and the glass plates.

22. The process of claim 19, wherein the glass slabs and the glass plates comprise photoinitiated seed crystals and the process further comprises photoinitiating the seed crystals after redrawing, but before etching the sacrificial glass to form a glass ceramic sensor substrate.

23. The process of claim 18, wherein forming the sensor substrate comprises:
translating a pulse laser across the sensor substrate in a desired location for each of the plurality of via holes to form a laser damaged region; and
etching the laser damaged region to form the plurality of via holes.

24. The process of claim 18, further comprising placing a light emitting film beneath the polymeric material.
